(19) United States
(12) Patent Application Publication
(10) Pub. No.: US 2011/0300290 A1
(43) Pub. Date: Dec. 8, 2011

(54) Device for fabricating electrode by roll to roll process and method for fabricating electrode

(75) Inventors: Hak Kwan Kim, Hanam (KR); Dong Hyeok Choi, Suwon (KR); Hong Seok Min, Yongin (KR); Hyun Chul Jung, Yongin (KR); Bae Kyun Kim, Seongnam (KR)

(73) Assignee: SAMSUNG ELECTRO-MECHANICS CO., LTD., Suwon (KR)

(21) Appl. No.: 12/926,228

(22) Filed: Nov. 3, 2010

(30) Foreign Application Priority Data
Jun. 4, 2010 (KR) 10-2010-0052738

(51) Int. Cl. C23C 14/56; B05D 5/12; C23C 14/54

(52) U.S. Cl. 427/10; 118/708; 118/718; 427/77; 427/78

(57) ABSTRACT

There are provided a device for fabricating an electrode by a roll-to-roll process and a method for fabricating an electrode. The device for fabricating an electrode includes an unwinding roll and a winding roll travelling an electrode material; a film forming roll disposed between the unwinding roll and the winding roll allowing the electrode material to travel along a cylindrical surface of the film forming roll and having a cooling unit cooling the electrode material; and an evaporation unit receiving a lithium source and mounted for the received lithium source to form a thin film in the electrode material positioned on the film forming roll. Thereby, the lithium is deposited in a vacuum atmosphere such that the process is simple and the deposition rate and the deposition uniformity of lithium can be improved.

### CROSS-REFERENCE TO RELATED APPLICATIONS

This application claims the priority of Korean Patent Application No. 10-2010-0052738 filed on Jun. 4, 2010, in the Korean Intellectual Property Office, the disclosure of which is incorporated herein by reference.

### BACKGROUND OF THE INVENTION

1. Field of the Invention

The present invention relates to a device for fabricating an electrode and a method for fabricating an electrode, and more particularly, to a device for fabricating an electrode of an energy storage device by a roll to roll process and a method for fabricating an electrode.

2. Description of the Related Art

With the development of an electric vehicle (EV) or a hybrid vehicle (HEV) using both an engine and a motor, a new method of improving fuel efficiency and a new energy storage device capable of satisfying energy capacity and output have been developed. In particular, a secondary battery (Ni-MH battery, Li ion battery (LiB), or the like) and an electrochemical capacitor (super capacitor) are currently being used as energy storage units for electric vehicles and hybrid vehicles.

The secondary battery, such as a LiB, one of a plurality of representative energy storage devices, has high energy density. However, the secondary battery has limited output characteristics as compared to the super capacitor. On the other hand, the super capacitor is a high-output storage device but has a lower energy density than the lithium ion battery. In order to overcome the problems inherent in each of the secondary batteries, a lithium (Li) pre-doping technology has been developed. A super capacitor called a lithium ion capacitor (LiC) has already been commercialized. The LiC has improved the energy density of the super capacitor three to four times, which is an existing electric double layer capacitor (EDLC) type.

It is the method of pre-doping Li that is the most important aspect of the LiC. The doping of lithium ions is uniform, due to the Li ion pre-doping, thereby making it possible to improve the energy density of the capacitor. Further, a separate lithium electrode is not needed due to the Li pre-doping such that the thickness of the cell is thin, thereby making it possible to implement the small-sized secondary battery. In addition, the lithium doping process is simple, such that the secondary battery can be mass-produced and the competitive price thereof can be improved.

### SUMMARY OF THE INVENTION

An aspect of the present invention provides a method for fabricating an electrode capable of fabricating an energy storage device with optimized cell performance like a secondary battery with improved output characteristics or a super capacitor with improved energy density characteristics, without greatly reducing energy density, by uniformly doping an electrode material with lithium ions while simplifying a fabricating process.

An aspect of the present invention provides a device for fabricating an electrode capable of fabricating an energy storage device with optimized cell performance like a secondary battery with improved output characteristics or a super capacitor with improved energy density characteristics, without greatly reducing energy density, by uniformly doping an electrode material with lithium ions while simplifying a fabricating process.

According to an aspect of the present invention, there is provided a device for fabricating an electrode including: an unwinding roll and a winding roll travelling an electrode material; a film forming roll disposed between the unwinding roll and the winding roll allowing the electrode material to travel along a cylindrical surface of the film forming roll and having a cooling unit cooling the electrode material; and an evaporation unit receiving a lithium source and mounted for the received lithium source to form a lithium thin film in the electrode material positioned on the film forming roll.

Preferably, the unwinding roll, the film forming roll, and the winding roll are driven in a one winding run manner.

Preferably, the lithium source toward the film forming roll from the evaporator unit is deposited in a vacuum atmosphere.

Preferably, the device for fabricating an electrode by a roll-to-roll process further includes: a measuring unit measuring a thickness of the deposited lithium thin film; and a controller controlling the deposited amount of lithium according to the measured thickness.

Preferably, the controller controls at least one of the deposition rate of lithium and the deposited amount of lithium according to the measured thickness.

Preferably, the cooling is performed in a water cooling process.

Preferably, the device for fabricating an electrode by a roll-to-roll further includes a doping device disposed subsequent to the winding roll and doping an electrode material with lithium ions from the lithium thin film by precipitating the electrode material in the electrolyte.

According to another aspect of the present invention, there is provided a method for fabricating an electrode including: supplying an electrode material while unwinding the electrode material from an unwinding roll; forming and cooling a lithium thin film on the electrode material while the electrode material supplied from the unwinding roll is travelling along a cylindrical surface of a film forming roll; and receiving the electrode material while winding the electrode material onto a winding roll.

Preferably, the unwinding roll, the film forming roll, and the winding roll are driven in a one winding run manner.

Preferably, a lithium source toward a film forming roll from an evaporator unit is deposited in a vacuum atmosphere.

Preferably, the method for fabricating an electrode by a roll-to-roll process further includes: measuring a thickness of the deposited lithium thin film; and controlling the deposited amount of lithium according to the measured thickness.

Preferably, the controlling controls at least one of the deposition rate of lithium and the deposited amount of lithium according to the measured thickness.

Preferably, the electrode material formed with the lithium thin film is cooled in a water cooling process.

Preferably, the method for fabricating an electrode by a roll-to-roll process, further includes after the electrode material is cooled, doping the electrode material with lithium ions by precipitating the electrode material in an electrolyte.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a diagram schematically showing a device for fabricating an electrode according to an exemplary embodiment of the present invention;

FIGS. 2A to 2C are cross-sectional views showing a process for forming a thin film pattern using the exemplary embodiment shown in FIG. 1; and

FIG. 3 is a diagram schematically showing a method for fabricating an electrode according to an exemplary embodiment of the present invention.

### DETAILED DESCRIPTION OF THE PREFERRED EMBODIMENT

Hereinafter, exemplary embodiments will be described in detail with reference to the accompanying drawings so that they can be easily practiced by those skilled in the art to which the present invention pertains. However, in describing the exemplary embodiments of the present invention, detailed descriptions of well-known functions or constructions are omitted so as not to obscure the description of the present invention with unnecessary detail.

In addition, like reference numerals denote parts performing similar functions and actions throughout the drawings.

In addition, unless explicitly described otherwise, “comprising” any components will be understood to imply the inclusion of other components but not the exclusion of any other components.

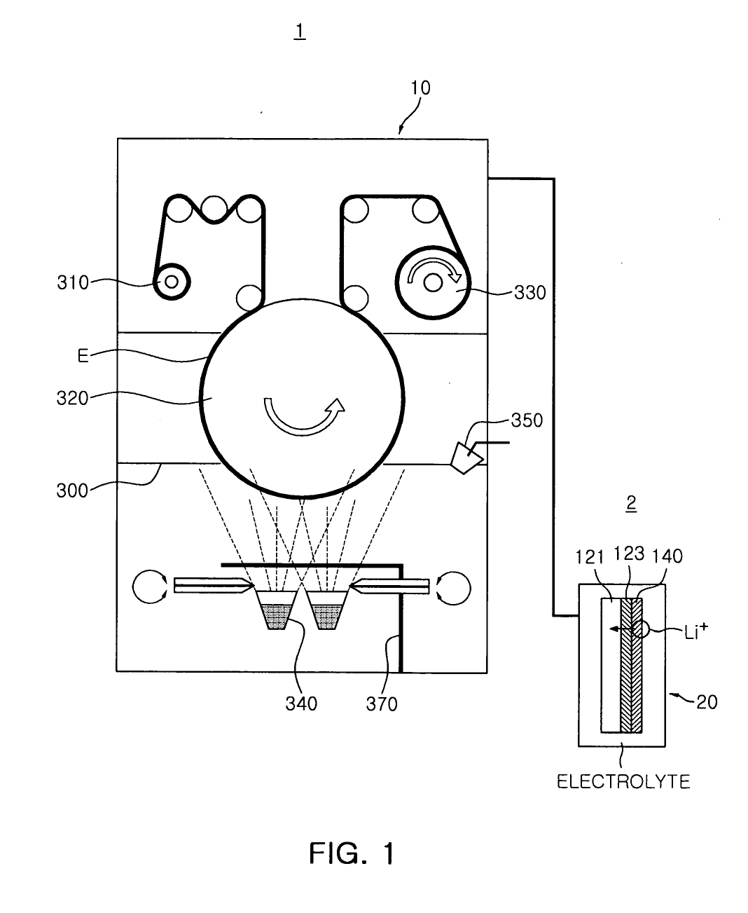

FIG. 1 is a diagram schematically showing a configuration of a device for fabricating an electrode according to an exemplary embodiment of the present invention.

Referring to FIG. 1, a device for fabricating an electrode according to an exemplary embodiment of the present invention is configured to include a lithium thin film forming device 1 and a doping device 2.

The lithium thin film forming device 1 according to the exemplary embodiment of the present invention includes a vacuum chamber 10, an unwinding roll 310 and a winding roll 330 mounted in the vacuum chamber 10 to travel an electrode material E, and a film forming roll 320 disposed between the unwinding roll 310 and the winding roll 330.

The electrode material E travels along a cylindrical surface of the film forming roll 320 and the electrode material E region disposed on the cylindrical surface of the film forming roll 320 becomes a deposited portion. The film forming roll 320 may include a cooling unit in which a coolant flows.

The electrode material E may travel along the cylindrical surface of the film forming roll 320 as an electrode material 123 itself and may also travel in the state in which the electrode material 123 is formed in a conductive sheet 121.

The conductive sheet 121 serves to transfer electrical signals to the electrode material 123 and collect accumulated charges and transfer them to the outside. The conductive sheet 121 may be made of conductive polymer, stainless steel, copper, nickel, or the like.

The electrode material E may be machined in a roll to roll manner by the unwinding roll 310 and the winding roll 330 and the film forming roll 320 disposed between the unwinding roll 310 and the winding roll 330. ‘Roll-to-roll’ that winds and machines a film type material to a rotating roll as it is. Therefore, the roll to roll manner can maximally reduce machining time, manpower, and the costs thereof.

Therefore, in the lithium thin film forming device 1, the other surface of the electrode material E on which lithium is not deposited is symmetrically disposed to face a deposition source, such that the lithium can be also deposited on the other surface thereof. In this manner, the lithium can be deposited on both surfaces of the electrode material, such that the mass production and the economical efficiency are more improved than the existing manner.

In addition, the unwinding roll 310, the winding roll 330, and the film forming roll 320 are driven in a one winding run manner. The ‘one winding run’ is a winding run in which any one of the plurality of rotating rolls is driven so as to drive all of the rotating rolls together, when the plurality of rotating rolls are wound with the film type material having. According to the present invention, the winding roll 330 is driven, such that the unwinding roll 310 and the film forming roll 320 can be driven together without a separate power source.

The lithium thin film forming device 1 includes a lithium source 340 receiving lithium, wherein the lithium source 340 is included in the vacuum chamber 10. Although not shown in FIG. 1, the lithium thin film forming device 1 may include a lithium evaporating unit, such as an electronic beam, in order to form the thin film on the surface of the electrode material E In order to prevent the thin film from being deposited on the other electrode material E, except for the desired depositing region, the lithium thin film forming device 1 may include a blocking layer 300.

When the electrode material E is positioned on the surface of the film forming roll 320 by the unwinding roll 310 and the winding roll 330, a shutter 370 is opened so that the evaporated lithium source can proceed (shown by an arrow) toward the electrode material E from the lithium source 340 and after the deposition completes, the shutter 370 is closed so that the evaporated lithium source does not proceed toward the film forming roll 320 when moving the electrode material E.

The lithium thin film forming device 1 may include a measuring unit 350 measuring a deposited amount of lithium. Actually, an amount required to perform the lithium doping is very small. Therefore, in order control the deposited amount of lithium, the lithium thin film forming device 1 may further include the measuring unit 350 measures the deposited amount of lithium and a controller (not shown) controlling the deposited amount of lithium according to the measured deposited amount.

The controller can control the deposition rate and/or deposited amount of lithium in order to control the deposited amount of lithium. For example, the controller can control the deposited amount of lithium by controlling the rotating time of the winding unit and/or the temperature of the heat source and/or the shutter 370, or the like.

When the thin film deposition is complete, the electrode material E travels to a position in the region other than the deposition region. Tension is applied to the electrode material E in a direction of the winding roll by the power source after the thin film is deposited to allow for travel.

The doping device 2 according to the exemplary embodiment of the present invention includes a doping chamber 20 in which an electrolyte is contained.

Processes, such as cutting or striping the electrode material, or the like, may be performed between the lithium thin film forming device 1 and the doping device 2.

The electrode material E may be doped with the lithium ions by precipitating the electrode material E formed with the lithium thin film in the electrolyte in the doping chamber 20.

In the case of the lithium ion capacitor according to the related art, an electroplating method has been used in order to perform the lithium ion doping. In the case of the electroplating method, a unit cell in which a first electrode fabricated by the electrode material, a separator that is an insulator, and a second electrode are stacked and a lithium electrode are precipitated in the electrolyte together. Then, the electrode material E is doped with the lithium ions by applying a predetermined power.

On the other hand, according to the present invention, there is no need to precipitate the second electrode, the separator, and the lithium electrode together. Further, since the lithium thin film layer is formed on the electrode material, the electrode material E is uniformly doped with the lithium ions at a very rapid speed by being diffused in the electrolyte. That is, the doping of the lithium ions is performed by precipitating the electrode material E in the electrolyte without applying power.

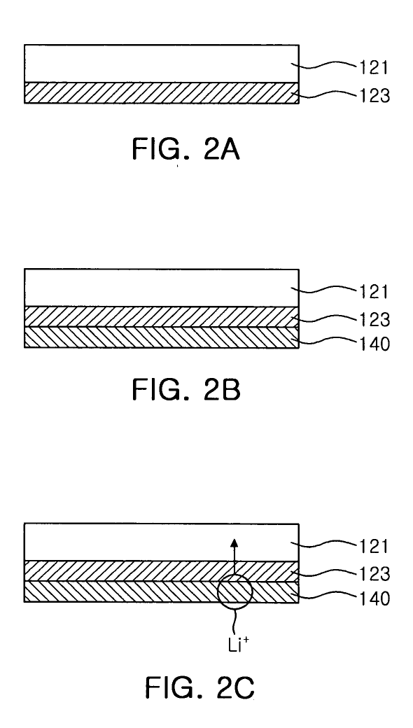

FIGS. 2A to 2C schematically show a process of fabricating an electrode according to an exemplary embodiment of the present invention, which are a process cross-sectional view showing in detail the deposition region of the film forming roll 320 for explaining the electrode material travelling, the lithium thin film forming process, and the lithium ion doping process in the lithium ion forming device 10 shown in FIG. 1.

As shown in FIG. 2A, an active material layer 123 is formed on a conductive sheet 121 on the film forming roll 320.

The active material layer 123 may use a material capable of reversibly supporting the lithium ions but is not limited thereto. For example, a carbon material such as graphite, hard carbon coke, or the like, a polyacen-based material, or the like, may be used.

In addition, the active material layer 123 may form a pole by being mixed with the conductive material. The conductive material is not limited to the foregoing materials. For example, acetylene black, ketjen black, graphite, metal powder, or the like, may be used.

The thickness of the active material layer 123 is not specifically limited. For example, the thickness of the active material layer 123 may be set to 10 to 100 μm.

The active material layer 123 may be formed on the conductive sheet 121. In the lithium ion forming device 10 according to the present invention, the electrode material is provided by being wound onto the winding roll 330 in the state in which the active material layer 123 is formed on the conductive sheet 121.

As shown in FIG. 2B, a lithium thin film 140 is formed by performing a deposition process on the electrode material E in the foregoing state. The deposition process may be executed by opening the shutter 370 shown in FIG. 1. According to the present invention, the lithium thin film 140 is formed by a vacuum deposition method.

As shown in FIG. 2C, the electrode material E is doped with lithium ions due to the lithium ions being diffused in the electrolyte. The doping of the lithium ions may be performed by precipitating the electrode material in the electrolyte without separately applying power.

Since the lithium thin film is uniformly applied over the conductive sheet 121 by the deposition process, the entire surface area thereof may be uniformly doped with the lithium. Since the surface area is uniformly doped with lithium, a super capacitor with improved energy density, high-output cycle characteristics, an extended lifespan, or the like, can be fabricated.

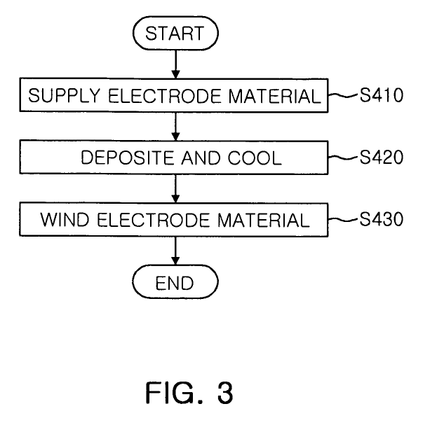

FIG. 3 is a flowchart schematically showing a method for fabricating an electrode according to an exemplary embodiment of the present invention.

According to an exemplary embodiment of the present invention, the electrode material E is supplied by being unwound from the unwinding roll (S410). The electrode material E may be the electrode material 123 itself and may be in the state in which it is formed in the conductive sheet 121.

The lithium thin film is formed on the electrode material and then, is cooled while the electrode material E supplied from the winding roll travels along the cylindrical surface of the film forming roll (S420). The cooling may be performed in a water cooling process. Further, the lithium thin film may be formed by the vacuum deposition method but should be uniformly formed over the electrode material E, if possible.

The electrode material is received while being wound onto the winding roll (S430). The power source is connected to the winding roll to control the rotating speed of the unwinding roll and the film forming roll and the deposition of the lithium thin film can be controlled according to the rotating speed of the winding roll.

Further, the lithium ions are doped by precipitating the electrode material E formed with the lithium thin film without separately applying power, thereby making it possible to fabricate the electrode for the energy storage device.

While the energy storage device according to the exemplary embodiment of the present invention is considered to be the lithium ion capacitor, this is described by way of example only. Therefore, the technical idea of the present invention can be applied to other energy storage devices.

As set forth above, unlike the existing lithium pre-doping technology, the method for fabricating an electrode and the device for fabricating an electrode according to the present invention deposits lithium in a vacuum atmosphere, thereby making it possible to simplify the process and improve the deposition rate and the deposition uniformity.

The winding type cell fabricated according to the present invention is uniformly doped with the desired amount of lithium, thereby making it possible to optimize the cell performance. As a result, the present invention can fabricate the secondary battery with the improved output characteristics the super capacitor with the improved energy density and high-output cycle characteristics, without greatly reducing the energy density.

While the present invention has been shown and described in connection with the exemplary embodiments, it will be apparent to those skilled in the art that modifications and variations can be made without departing from the spirit and scope of the invention as defined by the appended claims.

What is claimed is:

1. A device for fabricating an electrode by a roll-to-roll process, comprising:
an unwinding roll and a winding roll travelling an electrode material;
a film forming roll disposed between the unwinding roll and the winding roll to allow the electrode material to travel along a cylindrical surface of the film forming roll and having a cooling unit cooling the electrode material; and
an evaporation unit receiving a lithium source and mounted for the received lithium source to form a lithium thin film in the electrode material positioned on the film forming roll.

2. The device for fabricating an electrode by a roll-to-roll process of claim 1, wherein the unwinding roll, the film forming roll, and the winding roll are driven in a one winding run manner.

3. The device for fabricating an electrode by a roll-to-roll process of claim 1, wherein the lithium source toward the film forming roll from the evaporator unit is deposited in a vacuum atmosphere.

4. The device for fabricating an electrode by a roll-to-roll process of claim 1, further comprising:
a measuring unit measuring a thickness of the deposited lithium thin film; and
a controller controlling the deposited amount of lithium according to the measured thickness.

5. The device for fabricating an electrode by a roll-to-roll process of claim 4, wherein the controller controls at least one of the deposition rate of lithium and the deposited amount of lithium according to the measured thickness.

6. The device for fabricating an electrode by a roll-to-roll process of claim 1, wherein the cooling unit performs cooling in a water cooling process.

7. The device for fabricating an electrode by a roll-to-roll process of claim 1, further comprising a doping device disposed subsequent to the winding roll and doping the electrode material with lithium ions from the lithium thin film by precipitating the electrode material in the electrolyte.

8. A method for fabricating an electrode by a roll-to-roll process, comprising:
supplying an electrode material while unwinding the electrode material from an unwinding roll;
forming and cooling a lithium thin film on the electrode material while the electrode material supplied from the unwinding roll is travelling along a cylindrical surface of a film forming roll; and
receiving the electrode material while winding the electrode material onto a winding roll.

9. The method for fabricating an electrode by a roll-to-roll process of claim 8, wherein the unwinding roll, the film forming roll, and the winding roll are driven in a one winding run manner.

10. The method for fabricating an electrode by roll-to-roll process of claim 8, wherein the lithium thin film formed in the electrode material is formed by depositing a lithium source in a vacuum atmosphere.

11. The method for fabricating an electrode by a roll-to-roll process of claim 8, further comprising:
measuring a thickness of the deposited lithium thin film; and
controlling the deposited amount of lithium according to the measured thickness.

12. The method for fabricating an electrode by a roll-to-roll process of claim 11, wherein the controlling controls at least one of the deposition rate of lithium and the deposited amount of lithium according to the measured thickness.

13. The method for fabricating an electrode by a roll-to-roll process of claim 8, wherein the electrode material formed with the lithium thin film is cooled in a water cooling process.

14. The method for fabricating an electrode by a roll-to-roll process of claim 8, further comprising after the electrode material is cooled, doping the electrode material with lithium ions by precipitating the electrode material in an electrolyte.
